(19) United States
(12) Patent Application Publication
(10) Pub. No.: US 2026/0090416 A1
(43) Pub. Date: Mar. 26, 2026

(54) DISAGGREGATED SEMICONDUCTOR CHIP ON INTERPOSER WITHOUT THROUGH-SUBSTRATE VIAS

(71) Applicant: Intel Corporation, Santa Clara, CA (US)

(72) Inventors: Nitin A. Deshpande, Chandler, AZ (US); Atul Maheshwari, Portland, OR (US); Omkar G. Karhade, Chandler, AZ (US); Debendra Mallik, Chandler, AZ (US); Ritochit Chakraborty, Portland, OR (US)

(73) Assignee: Inter Corporation, Santa Clara, CA (US)

(21) Appl. No.: 18/896,483

(22) Filed: Sep. 25, 2024

(51) Int. Cl. H01L 23/498; H01L 23/00; H01L 25/00; H01L 25/065

(52) U.S. Cl. CPC H10W 70/65; H10W 70/685; H10W 90/00; H10W 90/401; H10W 90/701; H10W 80/312; H10W 80/327; H10W 90/794

(57) ABSTRACT

Devices and systems with interposers that do not include through-substrate vias, and methods of forming the same, are disclosed herein. In one example, a microelectronic assembly includes an interposer and one or more integrated circuit (IC) dies coupled to the interposer. The interposer includes one or more conductive traces and one or more vias, but the interposer does not include through-substrate vias. The respective IC dies are electrically coupled to the interposer via dielectric-to-dielectric and metal-to-metal bonds at the interface between the interposer and the respective IC dies.

### BACKGROUND

In some cases, a semiconductor chip may use a passive interposer with through-substrate vias (TSVs) to electrically connect multiple dies to each other and to other integrated circuit components. For example, the respective dies may be connected to the frontside of the interposer, and the backside of the interposer may be connected to another component, such as a package substrate or circuit board. Moreover, the interposer may include a substrate with layers of conductive traces and vias to provide routing to and from the dies on the frontside, along with TSVs extending through the substrate to provide routing between the dies on the frontside and other IC components on the backside (e.g., for power delivery and off-chip signaling). TSVs have various drawbacks, however, including higher resistive loss for power delivery and signaling, which reduces performance.

### BRIEF DESCRIPTION OF THE DRAWINGS

FIGS. 1A-B illustrate examples of disaggregated semiconductor chips on an interposer without through-substrate vias (TSVs).

FIGS. 2A-J illustrate an example process flow for forming a disaggregated semiconductor chip on a TSV-less interposer.

FIG. 3 illustrates an example of a microelectronic assembly with disaggregated semiconductor chips in accordance with certain embodiments.

FIG. 4 illustrates an example process flow for forming a device or system with disaggregated semiconductor chips in accordance with certain embodiments.

FIGS. 5A-C illustrate examples of disaggregated semiconductor chips in accordance with certain embodiments.

FIG. 6 illustrates a top view of a wafer and dies that may be included in a microelectronic assembly.

FIG. 7 illustrates a cross-sectional side view of an integrated circuit device assembly.

FIG. 8 illustrates a block diagram of an example electrical device.

### DETAILED DESCRIPTION

Disaggregated semiconductor chips may use a passive interposer to electrically connect multiple disaggregated active dies or “chiplets” to each other and to other integrated circuit (IC) components. In particular, a passive interposer is typically used when all of the active logic is on the chiplets—such as central processing units (CPUs), graphics processing units (GPUs), field-programmable gate arrays (FPGAs), and high-bandwidth memory (HBM) modules—and only wires are needed to connect the chiplets. In some cases, for example, the respective chiplets may be connected to the frontside of the interposer using a micro ball grid array (μBGA) interconnect or hybrid bond interconnect (HBI), and the backside of the interposer may be connected to another substrate using a ball grid array (BGA) interconnect, such as a package substrate or circuit board, which may include other IC components. Moreover, the interposer may include a substrate with layers of conductive traces and vias to provide routing to and from the chiplets on the frontside, along with through-substrate vias (TSVs) extending through the substrate to provide routing between the chiplets on the frontside and other IC components on the backside (e.g., for power delivery and off-chip signaling). For example, an interposer formed on a silicon substrate may include through-silicon vias extending through the silicon substrate to provide connections between the frontside and backside of the interposer.

TSVs have various drawbacks, however, including higher resistive loss for power delivery and signaling, which reduces performance. For example, TSVs add resistance to the electrical paths used for power delivery and signaling. This added resistance degrades the ability to deliver power, which reduces performance. TSVs are also very tall and have high aspect ratios, which creates capacitive coupling to other TSVs. This capacitive coupling, along with the added resistance, results in signal integrity loss for input/output (I/O) among the chiplets. This is particularly problematic for high-speed applications (e.g., high-speed serializers/deserializers (SerDes)) and may need to be mitigated using an additional metal layer—such as a package-side metal (PSM) layer and/or redistribution layer (RDL)—between the TSVs and the interconnect bumps or pads for isolation.

Accordingly, this disclosure presents embodiments of disaggregated semiconductor chips on a passive interposer without through-substrate vias (TSVs). In some embodiments, multiple disaggregated dies—which are also referred to herein as “chiplets”—are integrated on a substrate-less and TSV-less interposer using a hybrid bond interconnect (HBI) and a structural substrate on top. In hybrid bond interconnects, also known as direct bond interconnects, bonding pads on two opposing semiconductor dies and/or substrates are interconnected such that respective metal bonding pads on the dies are directly bonded together through metal-to-metal bonds (e.g., copper-to-copper bonds) without intervening conductive materials such as solder compounds between the bonding pads. Similarly, dielectric materials adjacent the respective metal pads are also bonded directly together through dielectric-to-dielectric bonds without intervening dielectric materials such as adhesives, molding compound, underfill material, and the like. For example, the interposer is formed by patterning an interconnect (e.g., metal layers of conductive traces and/or pads connected by vias) on a substrate without patterning any TSVs through the substrate. The chiplets are then attached to the frontside of the interposer via a hybrid bond interconnect (HBI), and a structural substrate is attached on top of the chiplets for added structural and mechanical stability. The original substrate on which the interposer was formed is then removed (e.g., by etching or grinding) to expose the first conductive layer on the backside of the interposer (e.g., first metal trace, pad, or via layer), and bumping is performed to form a ball grid array (BGA) interconnect on the backside of the interposer. In this manner, the completed semiconductor chip includes an interposer with no substrate nor TSVs.

The described embodiments may provide various advantages. For example, the described embodiments remove the need for TSVs in passive interposers, which enables disaggregated semiconductor chips to be formed on substrate-less and TSV-less interposers. In this manner, the resistive losses and capacitive coupling caused by TSVs are eliminated, thus improving power delivery to the chiplets and increasing the signal integrity of high-speed signals, which leads to improved power efficiency and performance. Further, the processing required for TSV formation is no longer needed, which reduces manufacturing costs.

Moreover, while the illustrated embodiments are shown with dies and chiplets implemented with frontside power delivery, the substrate-less and TSV-less interposers can also be used with dies and chiplets implemented with backside power delivery (e.g., where power is delivered via an interconnect on the backside of the die/chiplet substrate).

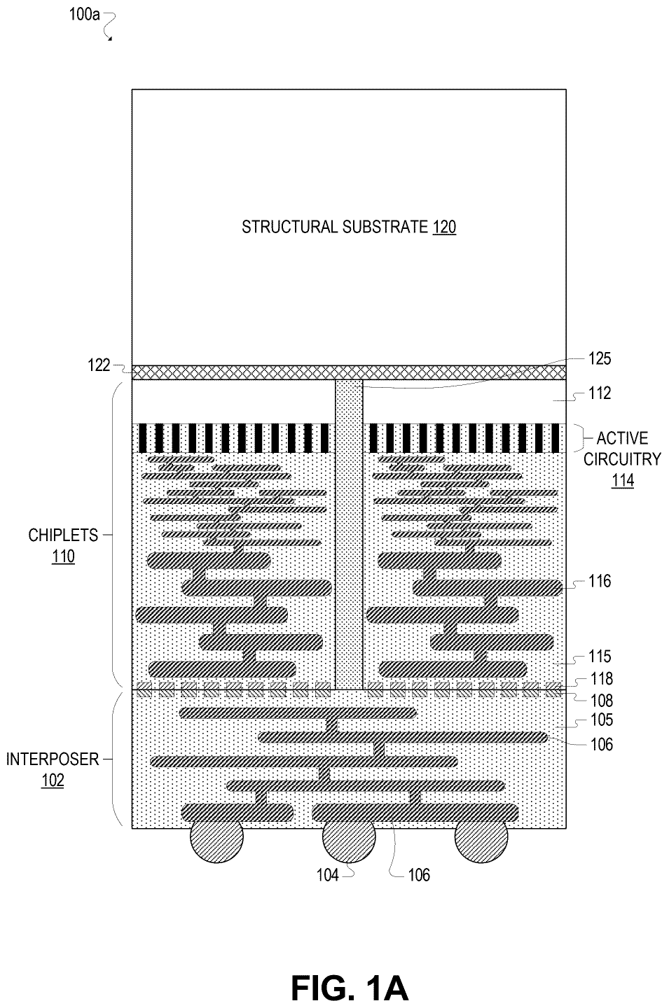

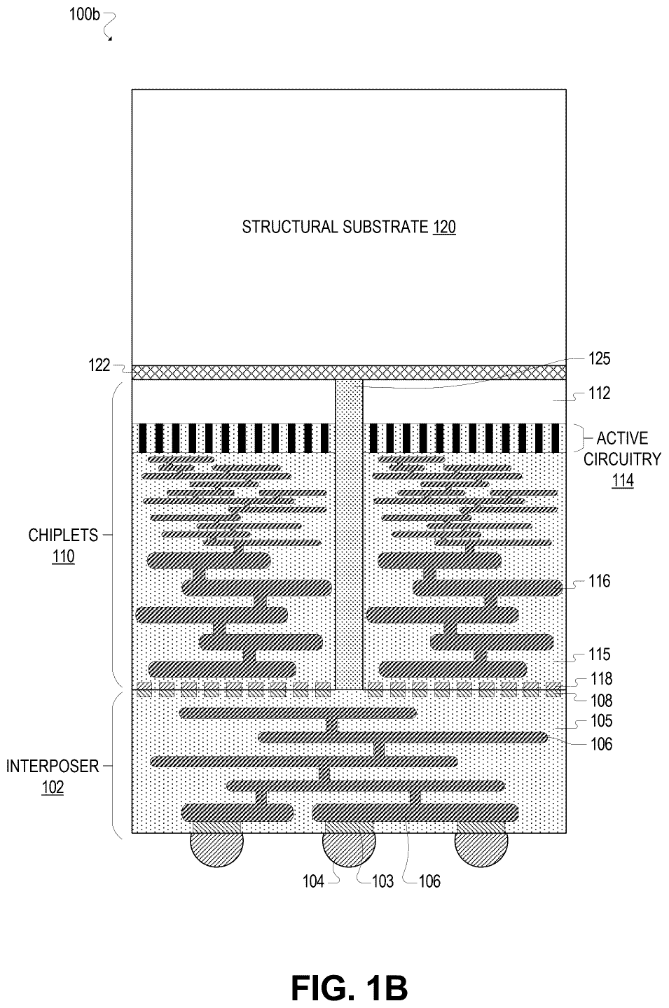

FIGS. 1A-B illustrate cross-section views of disaggregated semiconductor chips 100a,b on a passive interposer 102 without through-substrate vias (TSVs). In particular, the disaggregated semiconductor chips 100a,b include multiple active chiplets 110 hybrid bonded to an interposer 102, with a structural substrate 120 attached over the chiplets 110 for added structural and mechanical stability. Moreover, the interposer 102 does not include a substrate nor any TSVs. As a result, the interconnect bumps 104 on the backside of the interposer 102 land on the interconnect layers 106 of the interposer 102 rather than on TSVs. For example, in chip 100a of FIG. 1A, the bumps 104 land directly on the first metal layer 106 of the interposer 102. In chip 100b of FIG. 1B, however, the bumps 104 land on via or pad structures 103 below the first metal layer 106 of the interposer 102, which may be formed to avoid exposure of the first metal layer 106 during processing. The absence of TSVs in the interposer 102 eliminates the resistive losses and capacitive coupling caused by TSVs, which improves power efficiency and signal integrity and results in higher overall performance.

The interposer 102 includes metallization or interconnect layers 106 patterned with conductive traces and vias (along with bump landing pads 103 in chip 100b of FIG. 1B), which are separated by inter-layer dielectric (ILD) layers 105. The interposer 102 also includes conductive bumps 104 and pads 108 on the backside and frontside, respectively, which are electrically coupled to each other by the interconnect layers 106. The bumps 104 may be used to electrically couple the backside of the interposer 102 to another component (not shown), such as a package substrate or circuit board, via a ball grid array (BGA) interconnect. The pads 108 are used to electrically couple chiplets 110 to the frontside of the interposer 102 via a hybrid bond interconnect (HBI), as described further below.

The respective chiplets 110 include a substrate 112 (e.g., made of silicon) with active circuitry 114 formed thereon (e.g., complementary metal-oxide-semiconductor (CMOS) logic, transistors), metallization or interconnect layers 116 (e.g., patterned into conductive traces and vias), pads 118, and ILD layers 115. The active circuitry 114 and pads 118 are electrically coupled by the interconnect layers 116. Moreover, the pads 118 are used to electrically couple the chiplets 110 to the frontside of the interposer 102 via an HBI interconnect, as described further below.

In the illustrated embodiment, the chiplets 110 are electrically coupled to the interposer 102 via a hybrid bond interconnect (HBI). In particular, the chiplets 110 are hybrid bonded face down on the interposer 102, such that the frontside of the chiplets 110 is bonded to the frontside of the interposer 102. In this manner, a hybrid dielectric-to-dielectric and metal-to-metal bond is formed between the chiplets 110 and the interposer 102, such that the dielectric layer 115 on the face of the chiplets 110 is bonded to the dielectric layer 105 on the face of the interposer 102 and pads 118 on the chiplets 110 are bonded to pads 108 on the interposer 102.

The remaining area between the chiplets 110 is filled with an ILD 125. Moreover, a structural substrate 120 is attached over the chiplets 110 via a bonding layer 122 (e.g., an adhesive material such as silicon oxide, silicon nitride).

In this disclosure, a through-substrate via (TSV) may refer to a via that extends through the entire thickness of a substrate (e.g., between the frontside/backside), such as a through-silicon via in a silicon substrate, a through-glass via in a glass substrate, etc.

An interposer with no through-substrate vias (TSVs) may be referred to herein as a “TSV-less” interposer, and an interposer with no substrate (and thus no TSVs) may be referred to herein as a “substrate-less” and/or “TSV-less” interposer.

The terms “chiplet” and “die” may be used interchangeably herein. In some cases, a chiplet may refer to an integrated circuit (IC) die or assembly that implements a subset of the functionality (e.g., a functional block) of a more complex component or system, which may be integrated with other chiplets to implement the complete component or system. In some embodiments, for example, chiplets and/or dies may individually or collectively implement some or all of the functionality of one or more systems-on-a-chip (SoCs), microprocessors (e.g., central processing units (CPUs), graphics processing units (GPUs), vision processing units (VPUs), neural processing units (NPUs), other XPUs), field-programmable gate arrays (FPGAs), application-specific integrated circuits (ASICs), network interface controllers (NICs), input/output (I/O) devices and controllers, persistent storage devices, and/or memory devices and controllers, among other examples.

It should be appreciated that semiconductor chips 100a,b are merely shown as examples and numerous variations and alternative embodiments are also within the scope of this disclosure. In various embodiments, for example, certain elements of chips 100a,b may be modified, replaced, rearranged, omitted, and/or added.

As an example, chips 100a,b may include any number of chiplets 110, pads 103, 108, 118, bumps 104, and interconnect layers 106, 116 in various embodiments.

In various embodiments, the chiplets 110 may be attached to the interposer 102 using a variety of arrangements, including bonded to the surface of the interposer 102 (e.g., as shown in FIGS. 1A-B) or embedded within the interposer 102 (e.g., in a cavity), among other examples.

In various embodiments, any suitable interconnect technology may be used for the respective interconnects on the frontside and backside of the interposer 102 (e.g., between the interposer 102 and the chiplets 110 on the frontside and between the interposer 102 and another component on the backside (not shown)), including, without limitation, hybrid bond interconnects (HBI), micro ball grid array (μBGA) interconnects, and/or ball grid array (BGA) interconnects.

In various embodiments, certain elements/layers of chips 100a, b may have different arrangements than those shown in FIGS. 1A-B. Further, in some embodiments, chips 100a,b may include a variety of other components not shown in the illustrated embodiments. In some embodiments, for example, the interposer 102 and/or any of the chiplets 110 may include one or more metal-insulator-metal (MIM) devices (e.g., among the interconnect layers 106, 116), such as MIM capacitors or MIM diodes.

Examples of various materials that may be used to form the respective elements and/or layers of semiconductor chips 100a,b are provided below. In various embodiments, however, certain elements/layers of chips 100a,b may be made of materials other than those described below.

The conductive contacts (e.g., bumps 104, pads 108, 118) and interconnect layers/structures (e.g., conductive traces/vias 106, 116, pads 103) may be made of any suitable conductive or metal material(s), including, without limitation, aluminum (Al), copper (Cu), cobalt (Co), molybdenum (Mo), titanium (Ti), tantalum (Ta), tungsten (W), and compounds/alloys thereof (e.g., titanium nitride (TiN)). Thus, in some embodiments, the conductive contacts 104, 108, 118 and interconnect layers/structures 103, 106, 116 may be made of material(s) that include elements such as aluminum (Al), copper (Cu), cobalt (Co), molybdenum (Mo), titanium (Ti), tantalum (Ta), tungsten (W), and/or nitrogen (N).

The chiplet substrates 112 may be made of any suitable material(s), including, without limitation, silicon.

The structural substrate 120 may be made of any suitable material(s), including, without limitation, silicon.

The bonding layer 122 may be made of any suitable adhesive material(s), including, without limitation, silicon oxide (e.g., SiO₂) and/or silicon nitride (e.g., SiN, Si₃N₄). Thus, in some embodiments, the bonding layer 122 may be made of material(s) that include elements such as silicon (Si), oxygen (O), and/or nitrogen (N).

The inter-layer dielectrics (ILDs) 105, 115, 125 may be made of any suitable dielectric material(s), including, without limitation, silicon dioxide (SiO₂) (and/or other oxides of silicon), silicon nitride (SiN), silicon oxynitride (SiON), silicon oxycarbide (SiOC), and/or any other isolation oxides. Thus, in some embodiments, the ILDs 105, 115, 125 may be made of material(s) that include elements such as silicon (Si), oxygen (O), nitrogen (N), and/or carbon (C).

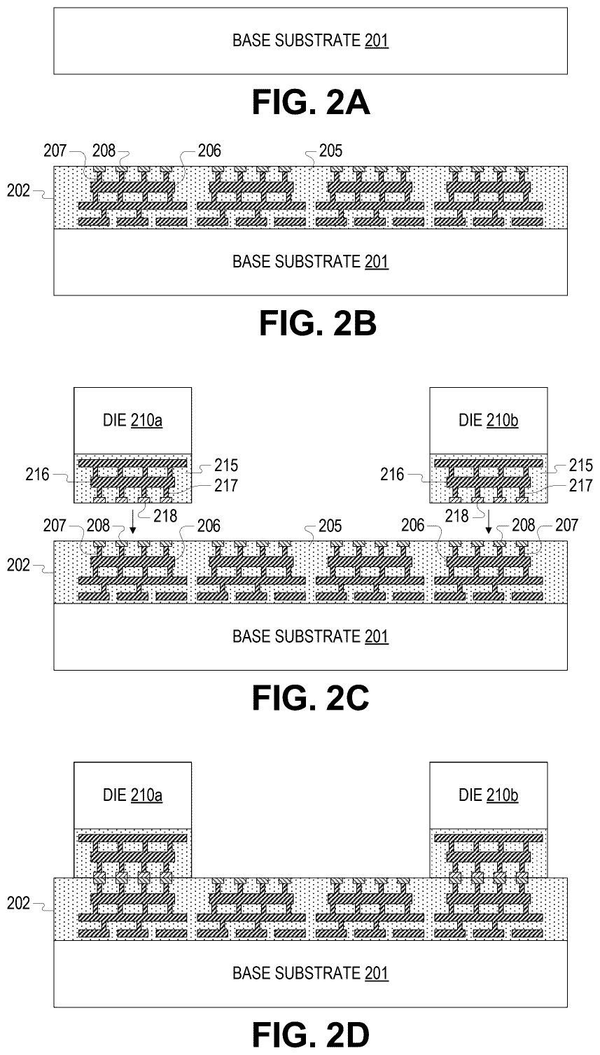

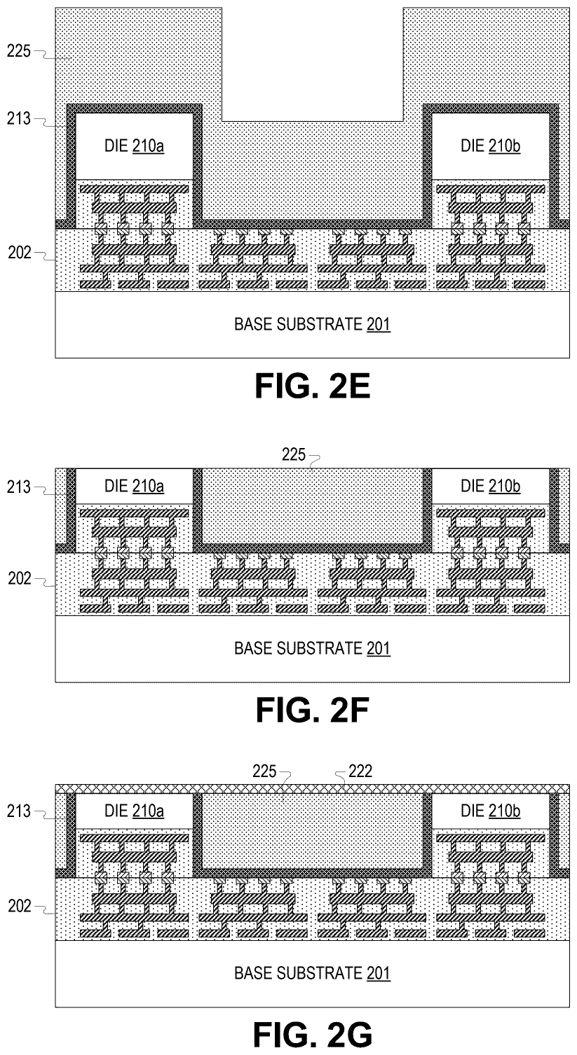

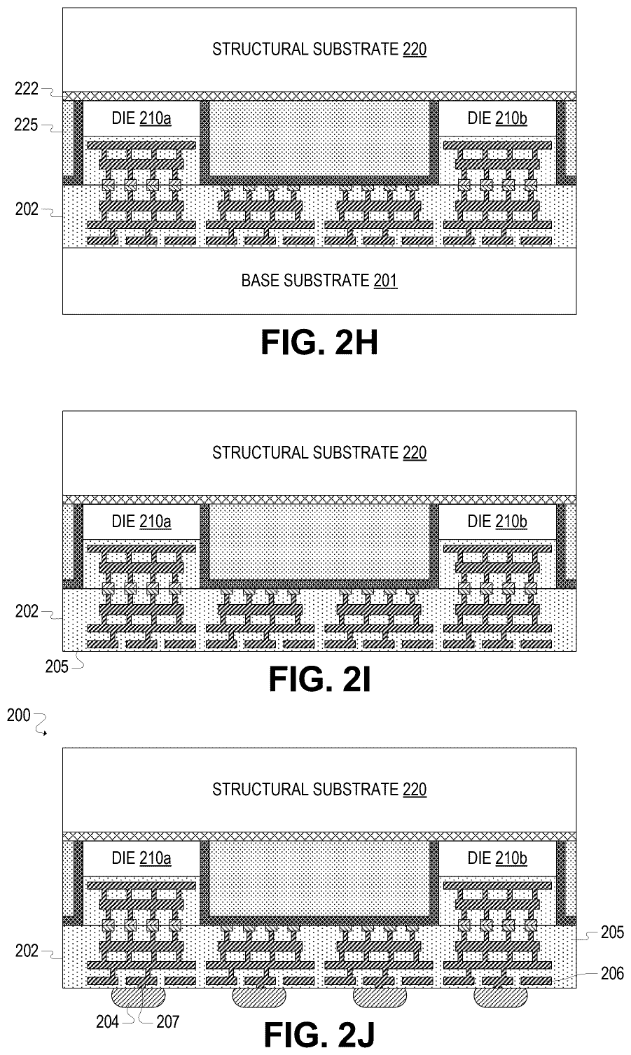

Additional embodiments of disaggregated semiconductor chips on TSV-less interposers, along with process flows for forming the same, are described in connection with FIGS. 2-5. The concepts described above with respect to chips 100a,b, including any modifications and variations thereof, also apply to the other embodiments described throughout this disclosure, and vice versa.

FIGS. 2A-J illustrate an example process flow for forming a disaggregated semiconductor chip 200 on a TSV-less interposer 202. In the illustrated example, FIGS. 2A-J show cross-section views (x-z plane) after performing various steps of the process flow. It will be appreciated in light of the present disclosure that the illustrated process flow is only one example methodology for arriving at a disaggregated semiconductor chip 200 on a TSV-less interposer 202.

The illustrated process flow eliminates the need for through-substrate vias (TSVs) in a passive interposer and uses hybrid bond interconnect (HBI) technology to attach dies (e.g., chiplets) to the interposer. In particular, deep trenches for TSVs are not created in the base substrate of the interposer. Rather, the metal layers (e.g., conductive traces) of the interposer are processed on the base substrate in the same manner as metal layers in other semiconductor manufacturing flows. Once the metal layers and bonding pads are processed, the interposer and dies are processed using an HBI attach flow, where the dies are attached to the interposer using a chip-to-wafer (C2W) or wafer-to-wafer (W2W) hybrid bonding flow, thus forming a hybrid bond interconnect between the dies and the interposer. The process requires careful alignment and cleanliness (e.g., similar to other silicon process flows). Post attach, the base substrate (e.g., silicon portion) of the interposer is removed (e.g., through etching or grinding) to expose the first conductive layer of the interposer (e.g., the first metal/trace, via, or pad layer). A bumping process is then performed on the interposer to complete the processing.

The illustrated process flow will now be described in further detail in connection with FIGS. 2A-J.

In FIG. 2A, a base substrate 201 is received. In some embodiments, the base substrate 201 may include silicon (e.g., a silicon wafer or panel).

In FIG. 2B, an interposer 202 is formed over the base substrate 201. For example, the interposer 202 may include one or more layers of conductive traces 206, vias 207, and/or pads 208, which collectively form an interconnect to electrically couple IC components (e.g., IC dies, package substrate, circuit board) that are subsequently attached to the frontside and backside of the interposer 202.

In some embodiments, for example, one or more interleaving dielectric layers 205 and metal layers 206 may be formed over the base substrate 201, such that the metal layers 206 are separated by dielectric layers 205. The metal layers 206 may be patterned (e.g., etched) into conductive traces 206, and vias 207 may be formed (e.g., etched and filled) through the intervening dielectric layers 205 to electrically couple the traces 206 in different layers.

Further, conductive (e.g., metal) pads 208 may be formed on the frontside (and/or backside) of the interposer 202, which are electrically coupled to the vias 207 and traces 206, thus enabling other components to be electrically coupled to the interposer 202, such as the IC dies 210a,b attached in FIG. 2D. In some embodiments, for example, the pads 208 may be hybrid bond interconnect (HBI) pads embedded in a dielectric layer 205, micro ball grid array (μBGA) or ball grid array (BGA) pads, and/or any other type of metal pads.

Notably, no through-substrate vias are needed in the base substrate 201, as the base substrate 201 will subsequently be removed in FIG. 2I. As a result, the interposer 202 does not include any through-substrate vias.

In some embodiments, the interposer 202 may also include other components, such as one or more metal-insulator-metal (MIM) devices (not shown). For example, the interposer 202 may include one or more MIM capacitors and/or MIM diodes among the layers of traces 206 and vias 207.

In FIG. 2C, multiples integrated circuit (IC) dies 210a,b (e.g., chiplets) are pick-and-place aligned face down on the frontside of the interposer 202, such that the pads 218 on the dies 210a,b are aligned with the pads 208 on the interposer 202.

The respective dies 210a,b may include a substrate with active circuitry (not shown), along with an interconnect that includes one or more layers of conductive traces 216, vias 217, and/or pads 218 separated by intervening dielectric layers 215, which may be used to electrically couple the active circuitry in the dies 210a,b to the interposer 202.

In some embodiments, the dies 210a,b may also include other components, such as one or more metal-insulator-metal (MIM) devices (not shown). For example, the dies 210a,b may include one or more MIM capacitors and/or MIM diodes among the layers of traces 216 and vias 217.

In FIG. 2D, the dies 210a,b are hybrid bonded to the interposer 202, such that the dielectric layers 215, 205 on the dies 210a,b and interposer 202 are respectively bonded together and the pads 218, 208 on the dies 210a,b and interposer 202 are respectively bonded together, thus forming a hybrid dielectric-to-dielectric and metal-to-metal bond between the dies 210a,b and the interposer 202. In this manner, the dies 210a,b are attached and electrically coupled to the interposer 202 via a hybrid bond interconnect (HBI).

In FIG. 2E, a dielectric liner 213 is formed over the interposer 202 and dies 210a,b, and the area above the liner 213 is filled with a dielectric layer 225 (e.g., an oxide).

In FIG. 2F, the dielectric liner 213 and dielectric layer 225 are planarized (e.g., by grinding).

In FIG. 2G, a bonding layer 222 is formed over the dielectric layers 213, 225 (e.g., by depositing an adhesive dielectric such as an oxide).

In FIG. 2H, a structural substrate 220 (e.g., a structural silicon wafer or panel) is attached on top of the dies 210a,b via the bonding layer 222. In this manner, the structural substrate 220 and the dielectric fill 225 between the dies 210a,b provide sufficient mechanical strength to enable the base substrate 201 to be removed (e.g., as shown in FIG. 2I).

In FIG. 2I, the base substrate 201 is removed by grinding and polishing (e.g., chemical mechanical polishing (CMP)) to expose the dielectric layer 205 on the backside of the interposer 202.

In FIG. 2J, vias 207 are etched on the backside of the interposer 202 to the first metal layer 206, and bumps 204 formed on the backside of the interposer 202 such that they land on the vias 207.

At this point, the disaggregated semiconductor chip 200 may be complete. In some embodiments, the semiconductor chip 200 may then be attached and electrically coupled to another IC component via the bumps 204 on the backside of the interposer 202, such as a package substrate and/or printed circuit board (PCB).

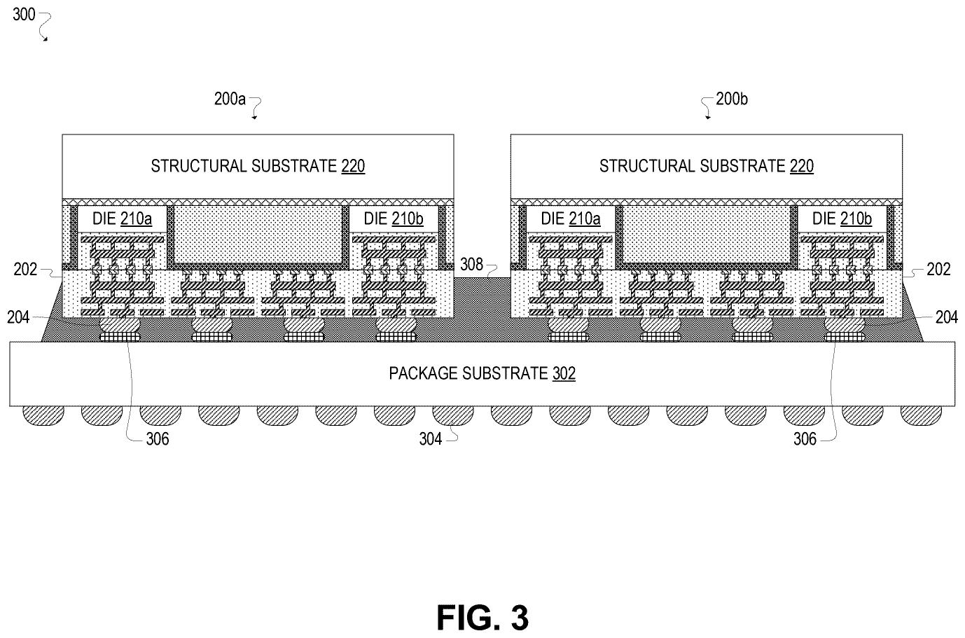

FIG. 3 illustrates a cross-section view of a microelectronic assembly 300 with disaggregated semiconductor chips 200a,b in accordance with certain embodiments. The microelectronic assembly 300 may also be referred to herein as an integrated circuit (IC) or IC package. In the illustrated embodiment, the microelectronic assembly 300 includes multiple disaggregated semiconductor chips 200a,b, which are implemented using the design of disaggregated semiconductor chip 200 of FIGS. 2A-J (with only some of the reference numerals shown for simplicity). For example, each disaggregated semiconductor chip 200a,b includes a TSV-less interposer 202, multiple dies 210a,b (e.g., chiplets) hybrid bonded to the interposer 202, and a structural substrate 220 bonded on top of the dies 210a,b. Moreover, the respective chips 200a,b are attached and electrically coupled to a package substrate 302. In particular, the conductive bumps 204 on the backside of the interposer 202 are bonded to conductive pads (not shown) on the frontside of the package substrate 302 using solder 306, and the gaps between the chips 200a,b and package substrate 302 are filled with underfill 308 (e.g., epoxy). The package substrate 302 also includes conductive bumps 304 on the backside, which serve as an interconnect (e.g., a BGA interconnect) to electrically couple the package substrate 302 to another component (not shown). In some embodiments, for example, the backside of the package substrate 302 may be electrically coupled to a printed circuit board (PCB) via the conductive bumps 304.

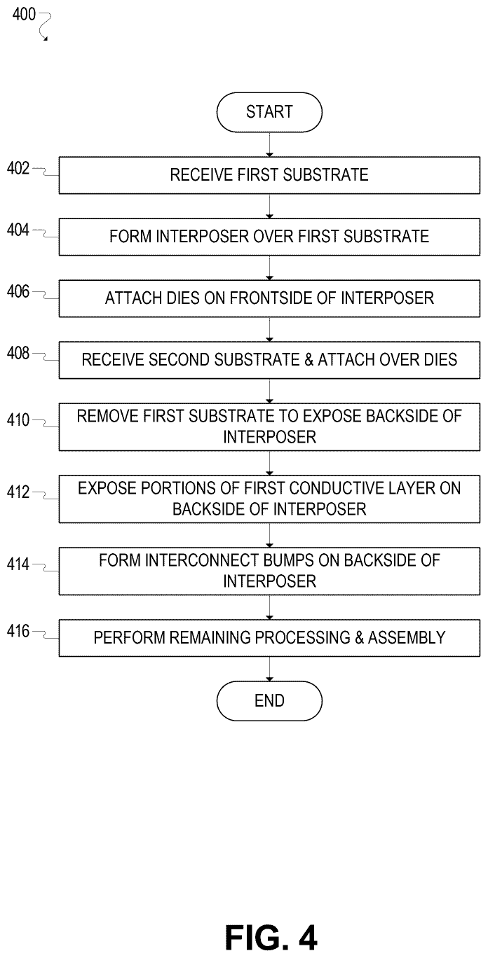

FIG. 4 illustrates an example process flow 400 for forming a device or system with disaggregated semiconductor chips in accordance with certain embodiments. In some embodiments, for example, the device or system may be, or may include, a microelectronic assembly or integrated circuit (IC) package with one or more disaggregated semiconductor chips on a TSV-less interposer, as described throughout this disclosure. It will be appreciated in light of the present disclosure that the illustrated process flow is only one example methodology for arriving at the example disaggregated semiconductor devices and systems shown and described throughout this disclosure.

The steps of the illustrated process flow may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metal-organic chemical vapor deposition (MOCVD), molecular beam epitaxy (MBE), atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The process flow begins at block 402 by receiving a first substrate, which may also be referred to as the base substrate. In some embodiments, the base substrate may include silicon (e.g., a silicon wafer).

The process flow then proceeds to block 404 to form an interposer over the base substrate. For example, the interposer may include one or more conductive traces, vias, and/or pads, which collectively form an interconnect to electrically couple IC components (e.g., dies, package substrate, circuit board) that are subsequently attached to the frontside and backside of the interposer.

In some embodiments, for example, one or more interleaving dielectric layers and conductive (e.g., metal) layers may be formed over the base substrate, such that the conductive layers are separated by dielectric layers. The conductive layers may be patterned (e.g., etched) into conductive traces, and vias may be formed (e.g., etched and filled) through the intervening dielectric layers to electrically couple the traces in different conductive layers. Further, conductive (e.g., metal) pads may be formed on the frontside and/or backside of the interposer, which are electrically coupled to the vias and traces, thus enabling other components to be electrically coupled to the interposer, such as the IC dies attached at block 406. In some embodiments, for example, the pads may be hybrid bond interconnect (HBI) pads embedded in a dielectric layer, micro ball grid array (μBGA) or ball grid array (BGA) pads, and/or any other type of metal pads.

Notably, no through-substrate vias are needed in the base substrate, as the base substrate will subsequently be removed at block 410. As a result, the interposer does not include any through-substrate vias.

In some embodiments, before the interposer is formed over the base substrate, an etch stop layer may be formed on the base substrate, such that after the interposer is formed, the etch stop layer is between the base substrate and the interposer. In this manner, when the base substrate is subsequently etched away at block 410, the etch stop layer will prevent the interposer from being etched into.

The process flow then proceeds to block 406 to attach one or more integrated circuit (IC) dies (e.g., chiplets) on the frontside of the interposer via a first level interconnect (FLI). In some embodiments, for example, the respective IC dies may be hybrid bonded to the frontside of the interposer, such that a hybrid dielectric-to-dielectric and metal-to-metal bond is formed at the interface between the interposer and the respective dies, thus electrically coupling the interposer and the respective dies via a hybrid bond interconnect (HBI). Alternatively, in some embodiments, the respective dies may be attached and electrically coupled to the interposer via a micro ball grid array (μBGA) interconnect or ball grid array (BGA) interconnect. Moreover, in some embodiments, the respective dies may include processing circuitry, memory circuitry, storage circuitry, and/or communication circuitry.

The process flow then proceeds to block 408 to receive a second substrate and attach the second substrate over the dies. The second substrate may be referred to as the structural substrate. In some embodiments, the structural substrate may include silicon (e.g., a structural silicon wafer). In some embodiments, the structural substrate may be bonded on top of the dies using a bonding layer between the dies and the structural substrate.

The process flow then proceeds to block 410 to remove the base substrate to expose the backside of the interposer. In some embodiments, for example, the base substrate may be removed from the backside of the interposer by grinding or etching away the base substrate, thus exposing the backside of the interposer. For example, if an etch stop layer was formed between the base substrate and the interposer at block 404, the backside of the base substrate may be etched until reaching the etch stop layer, thus avoiding etching into the interposer. Once the base substrate is removed, the interposer becomes a “substrate-less” interposer, as it no longer includes a substrate.

The process flow then proceeds to block 412 to expose portions of the first conductive layer on the backside of the interposer. In some embodiments, for example, the first conductive layer may include one or more conductive traces (e.g., the first metal layer), vias, or pads. Moreover, portions of the dielectric layer(s) below the first conductive layer may be etched away to expose the traces, vias, or pads in the first conductive layer.

The process flow then proceeds to block 414 to form one or more interconnect bumps on the backside of the interposer. In particular, one or more conductive (e.g., metal, solder) bumps may be formed on the backside of the interposer, such that they land on, and are electrically coupled to, the exposed traces, vias, or pads in the first conductive layer. In this manner, the bumps can be used as a second level interconnect (SLI) to electrically couple the interposer to another IC component, such as an IC package substrate or printed circuit board (PCB). In some embodiments, for example, the bumps may collectively form a ball grid array (BGA) interconnect.

The process flow then proceeds to block 416 to perform any remaining processing and assembly. For example, in wafer-level or panel-level process flows, the resulting panel or wafer may be diced to singulate the individual units of semiconductor chips on the wafer or panel. The singulated chips may then be attached to, or assembled in, an IC package, a printed circuit board (PCB), and/or an electronic device or system (e.g., microelectronic assembly 300, IC device 700, electronic device 800), among other examples. In some embodiments, for example, the backside of the interposer may be attached, and electrically coupled to, a package substrate via the interconnect bumps on the backside of the interposer, and in turn, the package substrate may be electrically coupled to a PCB.

At this point, the process flow may be complete. In some embodiments, however, the process flow may restart and/or certain blocks may be repeated. For example, in some embodiments, the process flow may restart at block 402 to continue forming semiconductor devices and systems with the same or similar design.

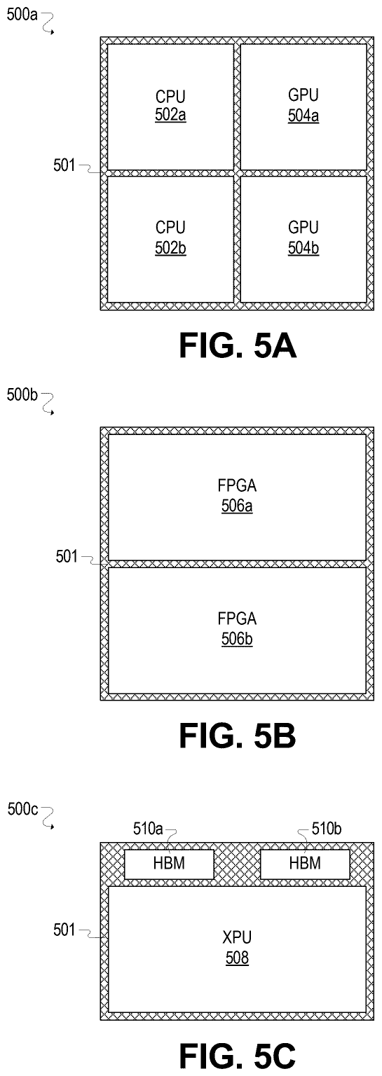

FIGS. 5A-C illustrate plan views of example disaggregated semiconductor chips 500a-c that may be implemented according to the embodiments described herein. In particular, chips 500a-c include disaggregated active dies or chiplets 502a-b, 504a-b, 506a-b, 508, 510a-b stacked on a passive interposer 501. The active dies/chiplets collectively include central processing units (CPUs) 502a,b, graphics processing units (GPUs) 504a,b, field-programmable gate arrays (FPGAs) 506a,b, an XPU 508 (e.g., any type or combination of processing units such as CPUs, GPUs, FPGAs, etc.), and high-bandwidth memory (HBM) modules 510a,b. Moreover, in some embodiments, the interposer 501 may be a substrate-less interposer implemented without through-substrate vias (TSVs), the active dies/chiplets 502a-b, 504a-b, 506a-b, 508, 510a-b may be hybrid bonded to the interposer 501, and/or a structural substrate (not shown) may be attached over the dies/chiplets 502a-b, 504a-b, 506a-b, 508, 510a-b for structural and mechanical stability, as described throughout this disclosure. In FIG. 5A, chip 500a includes multiple CPUs 502a,b and GPUs 504a,b coupled to interposer 501. In FIG. 5B, chip 500b includes multiple FPGAs 506a,b coupled to interposer 501. In FIG. 5C, chip 500c includes an XPU 508 and multiple HBM modules 510a,b coupled to interposer 501.

### Example Integrated Circuit Embodiments

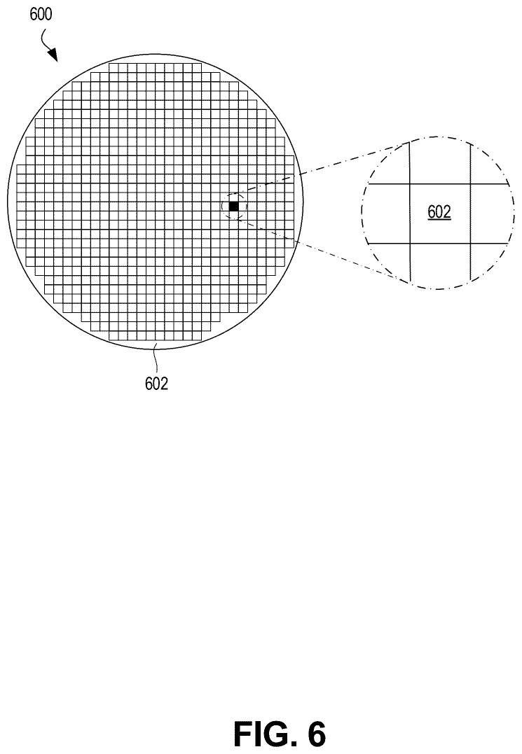

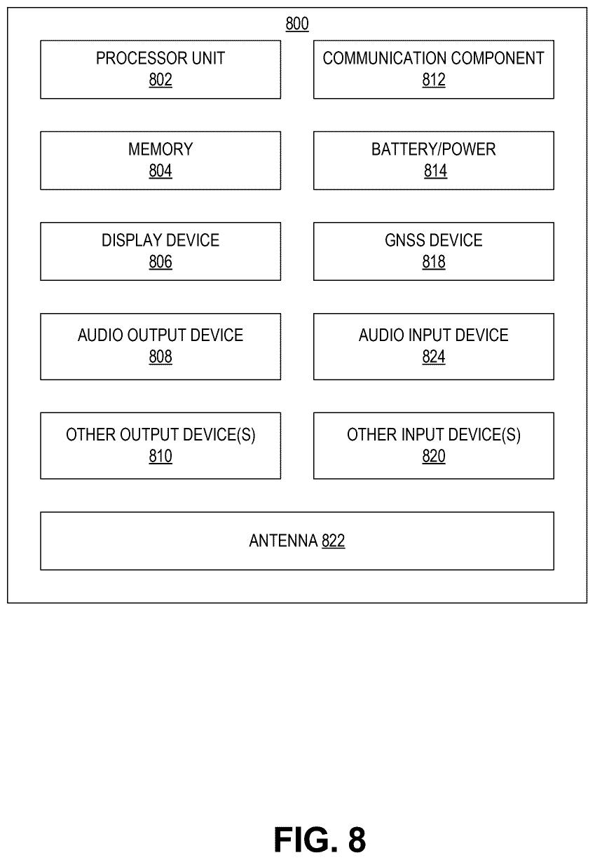

FIG. 6 is a top view of a wafer 600 and dies 602 that may be included in, or may include, any of the embodiments disclosed herein. In some embodiments, for example, the dies 602 may be included in the microelectronic assembles and semiconductor packages described throughout this disclosure (e.g., microelectronic assembles 100a-b, 200, 300, 500a-c, 700). The wafer 600 may be composed of semiconductor material and may include one or more dies 602 having integrated circuit structures formed on a surface of the wafer 600. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The die 602 may be any of the dies disclosed herein. The die 602 may include one or more transistors, supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processor unit (e.g., the processor unit 802 of FIG. 8) or other logic that is configured to store information in the memory devices or execute instructions stored in the memory array. Various ones of the microelectronic assemblies disclosed herein may be manufactured using a die-to-wafer assembly technique in which some dies are attached to a wafer 600 that include others of the dies, and the wafer 600 is subsequently singulated.

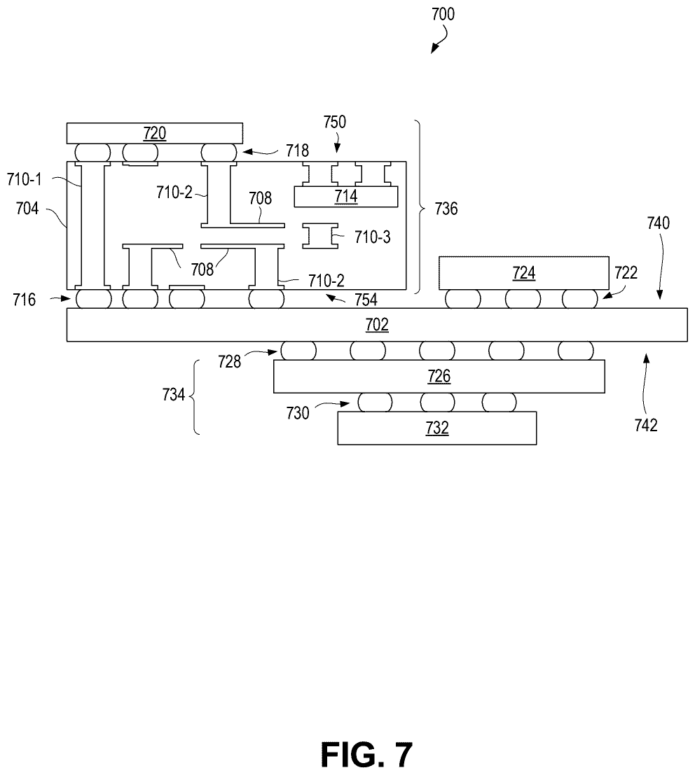

FIG. 7 is a cross-sectional side view of an integrated circuit device assembly 700 that may include any of the embodiments disclosed herein. In some embodiments, for example, interposer 704 may be implemented as a substrate-less interposer without through-substrate vias, and integrated circuit component 720 may be hybrid bonded to interposer 704, as described throughout this disclosure.

In some embodiments, the integrated circuit device assembly 700 may be a microelectronic assembly. The integrated circuit device assembly 700 includes a number of components disposed on a circuit board 702 (which may be a motherboard, system board, mainboard, etc.). The integrated circuit device assembly 700 includes components disposed on a first face 740 of the circuit board 702 and an opposing second face 742 of the circuit board 702; generally, components may be disposed on one or both faces 740 and 742. Any of the integrated circuit components discussed below with reference to the integrated circuit device assembly 700 may take the form of any suitable ones of the embodiments of the microelectronic assemblies disclosed herein.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 702. In other embodiments, the circuit board 702 may be a non-PCB substrate. The integrated circuit device assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702, and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 716 may serve as the coupling components illustrated or described for any of the substrate assembly or substrate assembly components described herein, as appropriate.

The package-on-interposer structure 736 may include an integrated circuit component 720 coupled to an interposer 704 by coupling components 718. The coupling components 718 may take any suitable form for the application, such as the forms discussed above with reference to the coupling components 716. Although a single integrated circuit component 720 is shown in FIG. 7, multiple integrated circuit components may be coupled to the interposer 704; indeed, additional interposers may be coupled to the interposer 704. The interposer 704 may provide an intervening substrate used to bridge the circuit board 702 and the integrated circuit component 720.

The integrated circuit component 720 may be a packaged or unpackaged integrated circuit product that includes one or more integrated circuit dies (e.g., the die 602 of FIG. 6) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider pitch or reroute a connection to a different connection. For example, the interposer 704 may couple the integrated circuit component 720 to a set of ball grid array (BGA) conductive contacts of the coupling components 716 for coupling to the circuit board 702. In the embodiment illustrated in FIG. 7, the integrated circuit component 720 and the circuit board 702 are attached to opposing sides of the interposer 704; in other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias 710, including but not limited to through hole vias 710-1 (that extend from a first face 750 of the interposer 704 to a second face 754 of the interposer 704), blind vias 710-2 (that extend from the first or second faces 750 or 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on a first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art. In embodiments where the interposer is a non-printed circuit board

The integrated circuit device assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The integrated circuit device assembly 700 illustrated in FIG. 7 includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

FIG. 8 is a block diagram of an example electrical device 800 that may include one or more of the embodiments disclosed herein. For example, any suitable ones of the components of the electrical device 800 may include one or more of the integrated circuit device assemblies 100a-b, 200, 300, 500a-c, 700, integrated circuit components 720, or integrated circuit dies 602 disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 800 can comprise one or more processor units 802 that are heterogeneous or asymmetric to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include other output device(s) 810 (or corresponding interface circuitry, as discussed above). Examples of the other output device(s) 810 may include an audio codec, a video codec, a printer, a wired or wireless transmitter for providing information to other devices, or an additional storage device.

The electrical device 800 may include other input device(s) 820 (or corresponding interface circuitry, as discussed above). Examples of the other input device(s) 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “under”, “between”, “adjacent”, “to”, and “on” as used herein may refer to a relative position of one layer or component with respect to other layers or components. For example, one layer “over”, “under”, or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

The term “package” generally refers to a self-contained carrier of one or more dice, where the dice are attached to or embedded in the package substrate, and may be encapsulated for protection, with integrated or wire-bonded interconnects between the dice, along with leads, pins, or bumps located on the external portions of the package substrate. The package may contain a single die, or multiple dice, providing respective functions. The package may be mounted on a printed circuit board for interconnection with other packaged integrated circuits and discrete components, forming a larger circuit.

The term “cored” generally refers to a substrate of an integrated circuit package built upon a board, card, or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core may allow for higher-density package architectures, as the through-vias may have relatively large dimensions and pitch compared to high-density interconnects.

The term “land side” generally refers to the side of the substrate of the integrated circuit package closest to the plane of attachment to a printed circuit board, motherboard, or other package. This is in contrast to the term “die side”, which generally refers to the side of the substrate of the integrated circuit package to which the die or dice are attached.

The terms “dielectric” and “dielectric material” generally refer to any type or number of non-electrically conductive materials. In some cases, dielectric material may be used to make up the structure of a package substrate. For example, dielectric material may be incorporated into an integrated circuit package as layers of laminate film or as a resin molded over integrated circuit dice mounted on the substrate.

The term “metallization” generally refers to metal layers formed on, over, and/or through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad”and may carry the same or similar meaning.

The term “bump” generally refers to a conductive layer or structure formed on a bond pad, which is typically made of solder or metal and has a round or curved shape, hence the term “bump”.

The term “substrate” generally refers to a planar platform that may include dielectric and/or metallization structures. A substrate may mechanically support and electrically couple one or more IC dies on a single platform, with encapsulation of the one or more IC dies by a moldable dielectric material. A substrate may include bumps or pads as bonding interconnects on one or both sides. For example, one side of the substrate, generally referred to as the “die side”, may include bumps or pads for chip or die bonding. The opposite side of the substrate, generally referred to as the “land side”, may include bumps or pads for bonding the package to a printed circuit board.

The term “assembly” generally refers to a grouping of parts into a single functional unit. For example, certain parts may be permanently bonded together, integrated together, and/or mechanically assembled (e.g., where parts may be removable) into a functional unit.

The terms “coupled” or “connected” means a direct or indirect connection, such as a direct electrical, mechanical, magnetic, or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

### EXAMPLES

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a microelectronic assembly, comprising: an interposer, wherein the interposer comprises one or more conductive traces and one or more vias, wherein the interposer does not comprise through-substrate vias; and one or more integrated circuit (IC) dies coupled to the interposer, wherein the respective IC dies are electrically coupled to the interposer via dielectric-to-dielectric and metal-to-metal bonds at an interface between the interposer and the respective IC dies.

Example 2 includes the microelectronic assembly of Example 1, further comprising a substrate, wherein the substrate is over the IC dies, and wherein the IC dies are over the interposer.

Example 3 includes the microelectronic assembly of Example 2, wherein a first side of the respective IC dies is coupled to the interposer via the dielectric-to-dielectric and metal-to-metal bonds, and wherein a second side of the respective IC dies is coupled to the substrate.

Example 4 includes the microelectronic assembly of any of Examples 2-3, wherein the substrate is a structural substrate.

Example 5 includes the microelectronic assembly of any of Examples 1-4, wherein: the interposer further comprises a plurality of conductive bumps, wherein the conductive bumps are on a first side of the interposer; and the respective IC dies are coupled to a second side of the interposer via the dielectric-to-dielectric and metal-to-metal bonds.

Example 6 includes the microelectronic assembly of Example 5, wherein the conductive bumps are coupled to a first conductive layer of the interposer, wherein the first conductive layer comprises one or more of the conductive traces, one or more of the vias, or one or more conductive pads.

Example 7 includes the microelectronic assembly of any of Examples 1-6, wherein the interposer does not comprise a substrate.

Example 8 includes the microelectronic assembly of any of Examples 1-7, wherein: at least one of the IC dies comprises one or more metal-insulator-metal (MIM) devices; or the interposer further comprises one or more MIM devices.

Example 9 includes the microelectronic assembly of Example 8, wherein the one or more MIM devices include at least one of an MIM capacitor or an MIM diode.

Example 10 includes the microelectronic assembly of any of Examples 1-9, wherein: the interposer is electrically coupled to a package substrate; and the package substrate is electrically coupled to a circuit board.

Example 11 includes the microelectronic assembly of any of Examples 1-10, wherein at least one of the IC dies comprises processing circuitry, memory circuitry, storage circuitry, or communication circuitry.

Example 12 includes a system, comprising: a circuit board; and an integrated circuit (IC) electrically coupled to the circuit board, wherein the IC comprises: an interposer, wherein the interposer comprises one or more conductive traces and one or more vias, wherein the interposer does not comprise a substrate; one or more IC dies over the interposer, wherein a first side of the respective IC dies is electrically coupled to the interposer via a hybrid dielectric-to-dielectric and metal-to-metal bond; and a structural substrate over the IC dies, wherein the structural substrate is coupled to a second side of the respective IC dies.

Example 13 includes the system of Example 12, wherein: the interposer further comprises a plurality of conductive bumps, wherein the conductive bumps are on a first side of the interposer; and the respective IC dies are coupled to a second side of the interposer.

Example 14 includes the system of Example 13, wherein the conductive bumps are coupled to a first conductive layer of the interposer, wherein the first conductive layer comprises one or more of the conductive traces, one or more of the vias, or one or more conductive pads.

Example 15 includes the system of any of Examples 12-14, wherein the interposer does not comprise through-substrate vias.

Example 16 includes the system of any of Examples 12-15, wherein the one or more IC dies include one or more chiplets.

Example 17 includes the system of any of Examples 12-16, wherein at least one of the IC dies comprises a central processing unit, a graphics processing unit, a field-programable gate array, or a memory device.

Example 18 includes a method, comprising: receiving a first substrate; forming an interposer over the first substrate, wherein the interposer comprises one or more conductive traces and one or more vias; attaching one or more integrated circuit (IC) dies to the interposer; attaching a second substrate over the one or more IC dies; and removing the first substrate from the interposer.

Example 19 includes the method of Example 18, wherein: the one or more IC dies are attached to a first side of the interposer; the first substrate is removed from a second side of the interposer; and the method further comprises, after removing the first substrate from the interposer, forming one or more conductive bumps on the second side of the interposer.

Example 20 includes the method of Example 19, wherein: the method further comprises, after forming the one or more conductive bumps on the second side of the interposer, attaching the second side of the interposer to a package substrate, wherein the interposer and the package substrate are electrically coupled via the one or more conductive bumps; and the method is a method of forming an IC package, wherein the IC package comprises the package substrate, the interposer, the one or more IC dies, and the second substrate.

Example 21 includes the method of any of Examples 18-20, wherein attaching the one or more IC dies to the interposer comprises hybrid bonding the one or more IC dies to the interposer, wherein a dielectric-to-dielectric and metal-to-meal bond is formed between the respective IC dies and the interposer.

Example 22 includes the method of any of Examples 18-20, wherein attaching the one or more IC dies to the interposer comprises attaching the one or more IC dies to the interposer via a ball grid array interconnect.

Example 23 includes the method of any of Examples 18-22, wherein removing the first substrate from the interposer comprises grinding or etching away the first substrate.

1. A microelectronic assembly, comprising:
an interposer, wherein the interposer comprises one or more conductive traces and one or more vias, wherein the interposer does not comprise through-substrate vias; and
one or more integrated circuit (IC) dies coupled to the interposer, wherein the respective IC dies are electrically coupled to the interposer via dielectric-to-dielectric and metal-to-metal bonds at an interface between the interposer and the respective IC dies.

2. The microelectronic assembly of claim 1, further comprising a substrate, wherein the substrate is over the IC dies, and wherein the IC dies are over the interposer.

3. The microelectronic assembly of claim 2, wherein a first side of the respective IC dies is coupled to the interposer via the dielectric-to-dielectric and metal-to-metal bonds, and wherein a second side of the respective IC dies is coupled to the substrate.

4. The microelectronic assembly of claim 1, wherein:
the interposer further comprises a plurality of conductive bumps, wherein the conductive bumps are on a first side of the interposer; and
the respective IC dies are coupled to a second side of the interposer via the dielectric-to-dielectric and metal-to-metal bonds.

5. The microelectronic assembly of claim 4, wherein the conductive bumps are coupled to a first conductive layer of the interposer, wherein the first conductive layer comprises one or more of the conductive traces, one or more of the vias, or one or more conductive pads.

6. The microelectronic assembly of claim 1, wherein the interposer does not comprise a substrate.

7. The microelectronic assembly of claim 1, wherein:
at least one of the IC dies comprises one or more metal-insulator-metal (MIM) devices; or
the interposer further comprises one or more MIM devices.

8. The microelectronic assembly of claim 1, wherein:
the interposer is electrically coupled to a package substrate; and
the package substrate is electrically coupled to a circuit board.

9. The microelectronic assembly of claim 1, wherein at least one of the IC dies comprises processing circuitry, memory circuitry, storage circuitry, or communication circuitry.

10. A system, comprising:
a circuit board; and
an integrated circuit (IC) electrically coupled to the circuit board, wherein the IC comprises:
an interposer, wherein the interposer comprises one or more conductive traces and one or more vias, wherein the interposer does not comprise a substrate;
one or more IC dies over the interposer, wherein a first side of the respective IC dies is electrically coupled to the interposer via a hybrid dielectric-to-dielectric and metal-to-metal bond; and
a structural substrate over the IC dies, wherein the structural substrate is coupled to a second side of the respective IC dies.

11. The system of claim 10, wherein:
the interposer further comprises a plurality of conductive bumps, wherein the conductive bumps are on a first side of the interposer; and
the respective IC dies are coupled to a second side of the interposer.

12. The system of claim 11, wherein the conductive bumps are coupled to a first conductive layer of the interposer, wherein the first conductive layer comprises one or more of the conductive traces, one or more of the vias, or one or more conductive pads.

13. The system of claim 10, wherein the interposer does not comprise through-substrate vias.

14. The system of claim 10, wherein the one or more IC dies include one or more chiplets.

15. The system of claim 10, wherein at least one of the IC dies comprises a central processing unit, a graphics processing unit, a field-programable gate array, or a memory device.

16. A method, comprising:
receiving a first substrate;
forming an interposer over the first substrate, wherein the interposer comprises one or more conductive traces and one or more vias;
attaching one or more integrated circuit (IC) dies to the interposer;
attaching a second substrate over the one or more IC dies; and
removing the first substrate from the interposer.

17. The method of claim 16, wherein:
the one or more IC dies are attached to a first side of the interposer;
the first substrate is removed from a second side of the interposer; and
the method further comprises, after removing the first substrate from the interposer, forming one or more conductive bumps on the second side of the interposer.

18. The method of claim 17, wherein:
the method further comprises, after forming the one or more conductive bumps on the second side of the interposer, attaching the second side of the interposer to a package substrate, wherein the interposer and the package substrate are electrically coupled via the one or more conductive bumps; and
the method is a method of forming an IC package, wherein the IC package comprises the package substrate, the interposer, the one or more IC dies, and the second substrate.

19. The method of claim 16, wherein attaching the one or more IC dies to the interposer comprises hybrid bonding the one or more IC dies to the interposer, wherein a dielectric-to-dielectric and metal-to-meal bond is formed between the respective IC dies and the interposer.

20. The method of claim 16, wherein removing the first substrate from the interposer comprises grinding or etching away the first substrate.
